(19) United States
(12) Patent Application Publication
(10) Pub. No.: US 2003/0136980 A1
(43) Pub. Date: Jul. 24, 2003

(54) Image pickup apparatus and exposure control method therefor

(76) Inventor: Malcolm Lin, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/345,274

(22) Filed: Jan. 16, 2003

(30) Foreign Application Priority Data
Jan. 18, 2002 (TW) 091100824

(51) Int. Cl. H01L 27/148; H01L 29/768

(52) U.S. Cl. 257/215

(57) ABSTRACT

An exposure control method for an image pickup apparatus with a CMOS image sensor comprises the steps: opening an mechanical shutter to guide incident light falling on the CMOS image sensor; generating a signal for eliminating residual image data, and initiating exposure controlled by an electronic shutter in the CMOS image sensor; generating an instruction for closing the mechanical shutter before the exposure finished; beginning to close the mechanical shutter after the exposure finished; and starting to read out the image data acquired as soon as the mechanical shutter has been closed completely.

### BACKGROUND OF THE INVENTION

1. Field of the Invention

This invention relates to an exposure control method for an image pickup apparatus having a Complementary Metal Oxide Semiconductor (CMOS) image sensor, and more particularly, to an exposure control method using electronic exposure of the CMOS image sensor in association with opening and closure time of a simple mechanical shutter.

2. The Related Art

Presently, most modern digital cameras or the like usually employ Charge Coupled Device (CCD) image sensors. For instance, such a digital camera with a CCD solid-state image sensor is disclosed in the U.S. Pat. No. 5,140,426. The digital camera also has a mechanical shutter in a lens module in front of the CCD solid-state image sensor for controlling exposure time of pixels on the CCD image sensor, and avoiding smear occurrence in the read-out period of image signals. Further, in order to achieve short and accurate exposure time for the digital camera, high close speed of the mechanical shutter is required. The complex structure of high speed mechanical shutter with increase system cost such that it is only suitable for high end products. Along with continued advances in semiconductor manufacturing technology, there is a new trend that CMOS image sensors will gradually replace CCD image sensors in the digital camera application for cost consideration.

Regular CMOS image sensor include an electronic rolling shutter for exposure control. Each line of image data must be read out immediately after the exposure period is completed, with reference to FIG. 6. A timing chart of exposure control for the image pickup apparatus is shown in Fig., in which the first image data D1 on the first line L1 starts to be read out after the exposure period from time T11 to time T21 Next the second image data D2 on the second line L2 is to be read out at time T22, when the image data D1 has just finished readout thereafter. In the following, the image data DN on line LN starts to be read out from time T2N after the image data DN-1 on line LN-1 has completed readout. Thus, it can be seen, the end-point time of the exposure period for each line of image data is determined by the readout speed of the image data on the previous line, so that the start time of the exposure period for each line of image data needs to be adjusted according to the different end-point time in order to obtain the same exposure amount for the entire image sensor array. However, in practice, these adjusted start time for all lines of image data will cause the lines to be exposed at different instants, which can result in image tear or distortion in horizontal direction, especially when shooting moving objects.

In order to attain the same start time of the exposure period for the image data in the entire array, another conventional image pickup apparatus constituted of CMOS image sensor has been provided to solve the aforesaid problem and control exposure for all lines of image data to be initiated synchronously at time TO with reference to FIG. 7. As show in FIG. 7, after the exposure is completed, each line of image data starts to be read out in sequence according to the same control scheme of the above-described electronic rolling shutter in the previous existing technique. Furthermore, an auxilliary light shielding device is utilized in the CMOS image pickup apparatus to obtain the same effective end-point time of the exposure period for the entire array, resulting in the uniform exposure period for the CMOS image sensor. That is, after certain time from T0 through T1, the auxilliary light shielding device is closed to shield light completely for controlling the same exposure amount and period for the entire array, with smear being eliminated at the same time. However, the available shortest exposure time still depends on the shutter speed of the light shielding device. The complicated light shielding design increases the system cost of the image pickup apparatus.

Recently, on the basis of the conventional rolling exposure technique as above mentioned, another image pickup apparatus design has been provided with a frame type exposure means in combination with an electronic rolling shutter. In the frame type image sensor operation, the entire array thereof is exposed to light at the same time, and then the image data acquired is temporarily stored on the corresponding pixels, subsequently the image data will be read out line by line. It is assumed that this kind of image pickup apparatus utilizes no mechanical light shielding device, relying on integrated circuit design in the image sensor to achieve the purpose of exposure control. However, in practice, such an integrated circuit design for the image pickup apparatus is too complicated to be realized perfectly in design and arrangement. Not only is it difficult to verify the effectiveness of the smear prevention mechanism, but also lower production yield will result in higher overall cost.

### SUMMARY OF THE INVENTION

An object of the present invention is to provide an image pickup apparatus and an exposure control method, in which the uniform exposure across the entire image sensor without smear occurrence that will provide excellent image quality can be realized easily by electronic exposure of a CMOS image sensor in association with opening and closure time of a simple mechanical shutter.

Another object of the present invention is to provide an image pickup apparatus and an exposure control method, in which the lens group design can be simplified, that directly translates into lower cost for the simple mechanical shutter which can be arranged outside the lens group to improve the performance remarkably.

In accordance with an aspect of the present invention, an exposure control method for an image pickup apparatus with a CMOS image sensor comprises the steps: opening an mechanical shutter to guide incident light falling on the CMOS image sensor; generating a signal for eliminating residual image data, and initiating the exposure controlled by an electronic shutter in the CMOS image sensor; generating a signal for closing the mechanical shutter before the exposure finished; the mechanical shutter actually starts to close after the exposure is completed; and starting to read out the image data acquired as soon as the mechanical shutter has been closed completely.

In accordance with another aspect of the present invention, an image pickup apparatus with a CMOS image sensor includes a mechanical shutter which can be opened after an power switch of the image pickup apparatus turned on and closed completely after the exposure controlled by an electronic shutter of the CMOS image sensor finished, subsequently, the image data starts to be read out.

A detailed explanation of the present invention will be given herebelow, with reference to the accompanying drawings of the preferred embodiments of the invention, which, however, should not be taken to be limitative to the present invention, but for better understanding thereof to those skilled in the art. In the drawings:

### BRIEF DESCRIPTION OF THE DRAWINGS

FIG. 1 is a block diagram illustrating the structure of an image pickup apparatus according to the present invention;

FIGS. 2a to 2c are flow charts showing three different operation examples of the image sensor apparatus in accordance with the present invention respectively;

FIG. 3 is a timing chart showing exposure control for the image pickup apparatus according to a first embodiment of the present invention.

FIG. 4 is a timing chart showing exposure control for the image pickup apparatus according to a second embodiment of the present invention.

FIG. 5 is a timing chart showing exposure control for the image pickup apparatus according to a third embodiment of the present invention.

FIG. 6 is a timing chart showing exposure control for a conventional image pickup apparatus including a CMOS image sensor which has an electronic rolling shutter.

FIG. 7 is a timing chart of exposure control for another conventional image pickup apparatus including a CMOS image sensor associated with an accessorial light shielding device.

### DETAILED DESCRIPTION OF THE PREFERRED EMBODIMENT

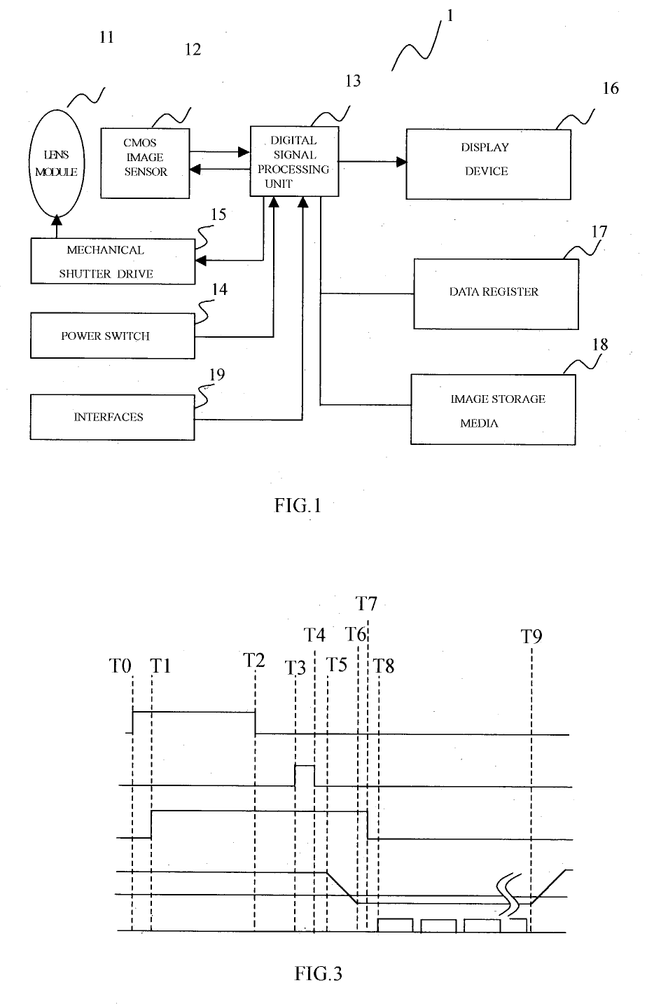

With reference to FIG. 1, an image pickup apparatus 1 in accordance with an embodiment of the present invention comprises a lens module 11, a CMOS image sensor 12, a digital signal processing unit 13, a power switch 14, a mechanical shutter drive 15, a display device 16, a data register 17, an image storage media 18 and interfaces 19. Further, the lens module 11 at least includes an iris, a mechanical shutter, and auto focusing and zooming control portion. The mechanical shutter is used to control the light falling on the surface of the CMOS image sensor 12. The CMOS image sensor 12 having an electronic shutter for performing electronic exposure can be selected from a passive-pixel sensor and an active-pixel sensor. The latter is a better option for enhancing signal to noise ratio and image quality. The digital signal processing unit 13 regarded as system controlling center of the image pickup apparatus is usually used for receiving external instruction transferred through the power switch 14 and the interfaces 19, generating control signals at certain time and controlling the whole timing for the operation of image data pickup, processing image data read out from the CMOS image sensor 12, compressing/decompressing the image data, forming the image on the display device 16 and so on. The digital signal processing unit 13 can also be constituted by an integrated chip, many single chips with various integrated circuit layout or discrete circuits. The power switch 14 is turned on to supply power to the image pickup apparatus 1, and the digital signal processing unit 13 gets ready for image pickup once receives the indication from the power switch. The mechanical shutter drive 15 which contains an electromagnetic valve or a stepping motor is controlled by the digital signal processing unit 13 for triggering the mechanical shutter of the lens module 11 at certain time to enter into the image view state or the image pickup state corresponding to the system design and operation mode of the image pickup apparatus 1. The display device 16 generally utilizes a colored liquid crystal display which has TV display function for viewing or replaying images. The data register 17 is used for depositing temporarily all related signals generated during processing and compressing/decompressing image data by the digital signal processing unit 13 and prior to image data sent out to a permanent storage device. The image storage media 18 is usually constituted by a non-volatile memory unit for storing image data compressed by the digital signal processing unit 13 and can also be designed to a mounted-in memory device or a removable memory device. And the interfaces 19 for transferring information between the interior and exterior of the image pickup apparatus 1 consist of various keys and buttons, such as a shutter button, and other indicators for LEDs, signal generator, sounder, and so on.

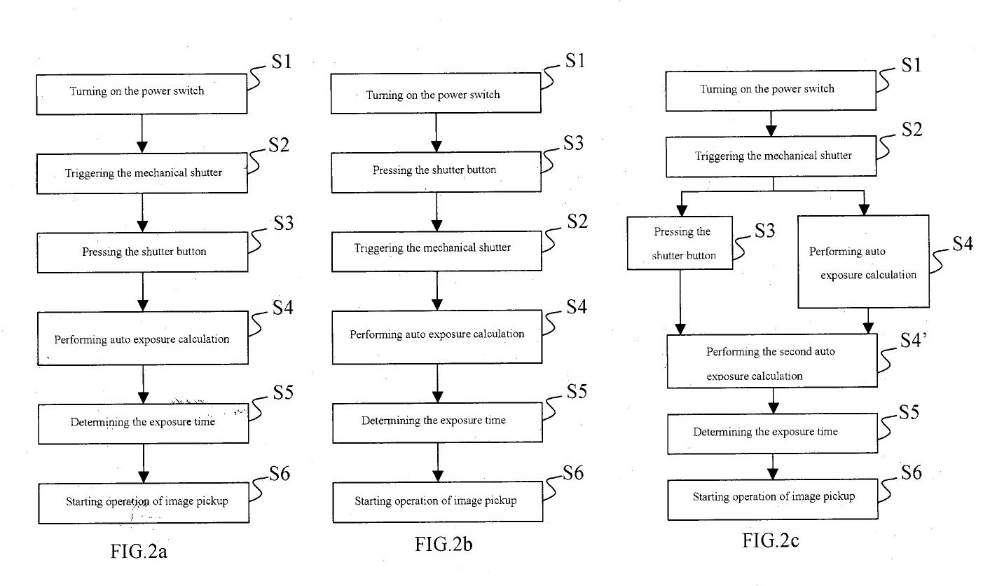

In operation of the foregoing embodiment, the electronic shutter in the CMOS image sensor 12 of the image pickup apparatus 1 is associated with the mechanical shutter to achieve the purpose of exposure control. FIG. 2a is a flow chart shows an operation means of the image pickup apparatus 1. As shown in FIG. 2a, the operation of the image pickup apparatus 1 contains in sequence: the first step indicated by S1 of turning on the power switch 14 to make the system firmware of the image pickup apparatus 1 start to run; triggering the mechanical shutter by the mechanical shutter drive 15 as the second step indicated by S2; and then after pressing the shutter button by user in the third step indicated by S3, the digital signal processing unit 13 keeping the mechanical shutter open and sampling some image data to perform auto exposure (AE) calculation in the fourth step indicated by S4 and determine the exposure time in the following step indicated by S5; starting operation of image pickup in the last step indicated by S6.

On the basis of the above description given on the example for the operation flow of the image pickup apparatus 1 as shown in FIG. 2a, those skilled in the art may make some suitable modifications thereof corresponding to other different states within the spirit and scope of the invention. For instance, another similar operation flow of the image pickup apparatus 1 is arranged, in which most steps of operation are the same as the first operation flow example with the same symbols but the two steps of operation indicated by S2 and S3 according to the first example that are transposed to prevent the CMOS image sensor 12 from being damaged potentially in excessive illumination with reference to FIG. 2b. That is, in this operation flow, the mechanical shutter is not triggered till the shutter button is pressed by user after the power switch 14 turned on. Further, in the third example of the operation flow as shown in FIG. 2c, which the steps of the same operation as the first example of the operation flow are also indicated correspondingly by the same symbols therein, the mechanical shutter is triggered as the step indicated S2 with AE calculation being performed synchronously as the step indicated S4 after the power switch 14 turned on as the step indicated S1, and then the second AE operation indicated S4′ and determining the accurate exposure time indicated S5 are performed in turn after the shutter button pressed by user as the step indicated S3, finally the operation of image pickup indicated S6 starting.

In accordance with the above illumination, the mechanical shutter is triggered by the mechanical shutter drive 15. Assuming that a bistable electromagnetic valve is used as the mechanical shutter drive 15, the mechanical shutter is triggered to let light strike on the surface of the CMOS image sensor 12 through the lens module 11 when the electromagnetic valve is electrified and an open control signal thereof is set, and will keep open after the electromagnetic valve finished charging. But when the electromagnetic valve is electrified and a close control signal thereof is set, the mechanical shutter is closed to stop light and shield the CMOS image sensor 12, and will keep closed after the electromagnetic valve finished charging. Moreover, the close control signal of the electromagnetic valve can be set as a high level signal to make the mechanical shutter closed once the electromagnetic valve has accumulated enough power, and then converted to a low level signal for ending. And generally, the time for the bistable electromagnetic valve accumulating enough power is approximate 3 millisecond to 50 millisecond, but about 15 millisecond in common use.

Moreover, with reference to the timing chart of exposure control for the image pickup apparatus 1 as shown in FIG. 3, in the course of image pickup operation, the CMOS image sensor 12 generates a high level signal for eliminating residual signals at the point of time T0 firstly, and converts the high level signal to a low level signal up to the point of time T2. During the period From T0 to T2 for the high level signal which is generally a few microsecond to a few millisecond, all residual signals on the whole array of the CMOS image sensor 12 caused by the accumulated charges generated for the light falling thereon has been eliminated. Further, a high level signal for closing the mechanical shutter is set during the point of time T1 after certain suitable delay which is acquired by calculating or measuring in advance has been elapsed from the point of time T0, and the point of time T7 at which the high level signal starts to be converted to a low level signal in succession.

The electronic exposure of the CMOS image sensor 12 starts from the point of time T2, and the electronic exposure period is set in advance from T2 to T3 according to the operation flow of the image pickup apparatus 1, such as the three examples as shown in FIGS. 2a to 2c respectively, which is commonly about several microsecond to tens millisecond, even extending to several second. Then a high level signal for exposure being finished is set during the period from the point of time T3 to the point of time T4 at which the high level signal is subsequently converted to a low level signal, which is generally about several microsecond, but can be extended to ten microsecond in practice. Next, at the point of time T5, the mechanical shutter starts to be closed for the electromagnetic valve having been charged adequately. The mechanical shutter has been closed completely till the point of time T6, and the signal for closing the mechanical shutter is converted to a low level signal after a certain delay which is about 1 to 5 millisecond for making sure whether the operation for closing mechanical shutter is accomplished. Then, the CMOS image sensor 12 starts to read out image data from the point of time T8, and the mechanical shutter reopens at the point of time T9 for next image data after all the image data read out by the digital signal processing unit 13.

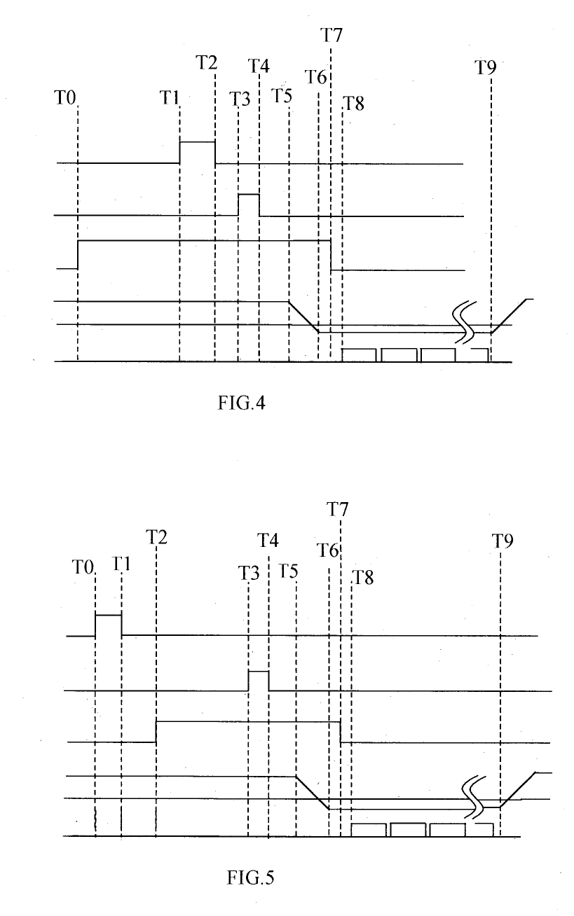

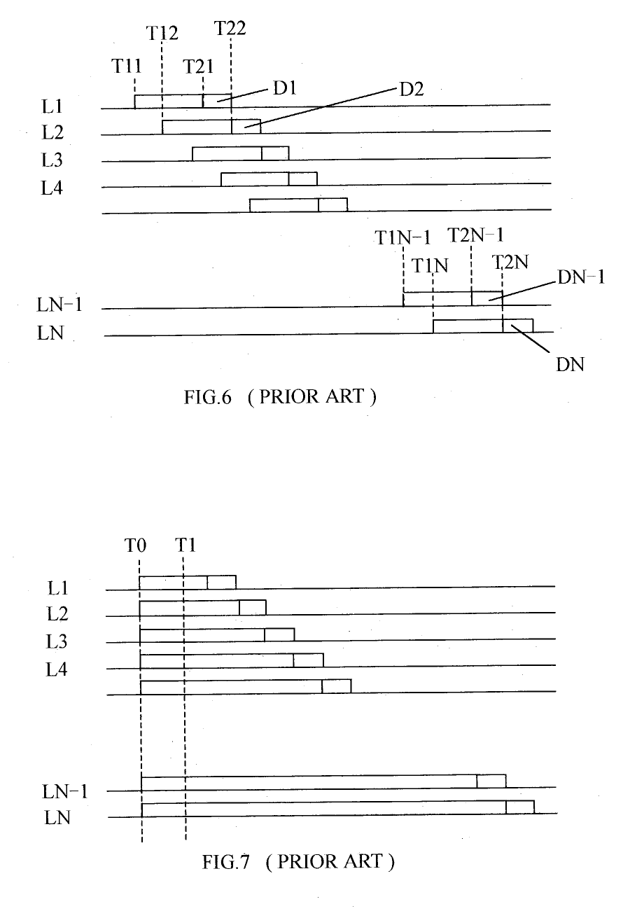

On the assumption that the electronic exposure period of the CMOS image sensor 12 is comparatively short, the period for eliminating residual signals needs to be adjusted for the relatively long time to charge the electromagnetic valve for closing the mechanical shutter. So that another timing chart showing exposure control for the image pickup apparatus 1 according to a second embodiment of the present invention will be described below with reference to FIG. 4. As shown in FIG. 4, a high level signal for closing the mechanical shutter is set firstly at the point of time T0. By reason of the period from the point of time T0 to T5 for the electromagnetic valve accumulating enough power measured in advance, a high level signal for eliminating residual signals is generated at a proper point of time T1 and converted to a lower level signal for ending the elimination, so that the period from the point of time T1 to T2 is commonly about several microsecond, but extended to several millisecond in practice. After the residual signals eliminated, the following operations in corresponding periods as shown in FIG. 4 are the same as those disclosed in FIG. 3, such as the electronic exposure in the period from the point of time T2 to T3, setting the high level signal for the exposure being finished in the next period from the point of time T3 to T4, closing the mechanical shutter in the following period from the point of time T5 to T6, and in succession starting to read out the image data at the point of time T7 after generating a low level signal for closing mechanical shutter. It is also the same as shown in FIG. 3 that the mechanical shutter reopens at the point of time T9 for picking up next image data.

Moreover, if the electronic exposure period of the CMOS image sensor 12 is comparatively long, the period for eliminating residual signals also needs to be adjusted for the fixed time to charge the electromagnetic valve for closing the mechanical shutter. So that further timing chart showing exposure control for the image pickup apparatus 1 according to a third embodiment of the present invention will be described below with reference to FIG. 5. As shown in FIG. 5, a high level signal for eliminating residual signals is set firstly at the point of time T0 and then converted to a low level eliminating signal at the point of time T1, so that the period from the point of time T0 to T1 for the high level eliminating signal is commonly about several microsecond, but extended to several millisecond in practice. Because the period from the point of time T2 to T5 for charging the electromagnetic valve enough is invariable and measured aforehand, a high level signal for closing the mechanical shutter is generated at the proper point of time T2. In the following, the operations in corresponding periods are performed in turn, which are composed of electronic exposure in the period of the point of time T1 to T3, setting the exposure finished signal as the high level signal firstly and then converting the high level signal to the low level signal for ending the electronic exposure during the point of time T3 and T4, closing the mechanical shutter between the point of time T5 and T6 and starting to read out the image data from the point of time T8. After the image data readout completed, the mechanical shutter will reopen at the point of time T9 for picking up next image data with reference to FIG. 5.

Furthermore, as mentioned above, the mechanical shutter is utilized to achieve the purpose of shielding light completely for avoiding the smear occurrence in the present invention, with all the image data starting to be read out just after the mechanical shutter is closed completely. On the other hand, the exposure of the image data is controlled by the electronic shutter in the CMOS image sensor 12 and the mechanical shutter is closed entirely after the electronic exposure finished, so the accuracy and shutter speed of the mechanical shutter is not required any more for the image pickup apparatus design, thereby manufacturing cost has been reduced and the flexibility for designing the lens module 11 has been improved. For example, the mechanical shutter can be mounted in front of the lens module 11 or between the lens module 11 and the CMOS image sensor 12.

While the present invention has been described with respect to what are presently considered to be the preferred embodiments, it is to be understood that the invention is not limited to the disclosed embodiments. Contrarily, the present invention is intended to cover various modifications and equivalent arrangements that may be resorted to within the spirit and scope of the claims thereof.

What is claimed is:

1. An exposure control method for an image pickup apparatus at least comprising the following steps:
(1) opening an mechanical shutter before initiating exposure controlled by an electronic shutter in a CMOS image sensor therefor;
(2) generating a signal for eliminating residual image data, and initiating said exposure controlled by said electronic shutter in said CMOS image sensor;
(3) generating an instruction for closing said mechanical shutter before said exposure finished;
(4) beginning to close said mechanical shutter after said exposure has completed; and
(5) starting to read out image data acquired during said exposure period of said CMOS image sensor after said mechanical shutter closed completely.

2. The method as claimed in claim 1, wherein said signal for eliminating residual image data is generated prior to said instruction for closing said mechanical shutter.

3. The method as claimed in claim 1, wherein said instruction for closing said mechanical shutter is generated prior to said signal for eliminating residual image data adapted to said comparatively short exposure period.

4. The method as claimed in claim 1, wherein said instruction for closing said mechanical shutter is generated after residual image data eliminated adapted to said comparatively long exposure period.

5. The method as claimed in claim 1, wherein a delay exists between the point of time for closing said mechanical shutter completely and another point of time for starting to read out the image data acquired during said electronic exposure period of said CMOS image sensor.

6. The method as claimed in claim 1, wherein said point of time for starting to read out the image data acquired during said electronic exposure period of said CMOS image sensor is after said instruction for closing said mechanical shutter finished.

7. The method as claimed in claim 1, wherein said point of time for starting to read out the image data acquired during said electronic exposure period of said CMOS image sensor is prior to said instruction for closing said mechanical shutter finished.

8. An image pickup apparatus at least comprising:
a power switch controlling power supply therefor;
a CMOS image sensor which has an electronic shutter for performing electronic exposure;
a lens module containing a mechanical shutter for controlling light falling on said CMOS image sensor;
a mechanical shutter drive for triggering said mechanical shutter;
interfaces for transferring information between the interior and exterior thereof;
a digital signal processing unit for receiving external instruction transferred through said power switch and said interfaces, generating control signals at certain time and controlling the whole timing for the operation of image data pickup; and
whereby triggering said mechanical shutter by said mechanical shutter drive before initiating exposure of said electronic shutter in said CMOS image sensor;
generating a signal for eliminating residual image data and initiating exposure of said electronic shutter in said CMOS image sensor;
generating an instruction for closing said mechanical shutter before said exposure finished;
beginning to close said mechanical shutter after said exposure finished; and
starting to read out image data acquired during said exposure period of said CMOS image sensor after said mechanical shutter closed completely.

9. The apparatus as claimed in claim 8, wherein said mechanical shutter is mounted in front of said lens module.

10. The apparatus as claimed in claim 8, wherein said mechanical shutter is mounted between said lens module and said CMOS image sensor.

11. The apparatus as claimed in claim 8, further comprising a display device generally utilizing a colored liquid crystal display which has TV display function for viewing or replaying image formed from said digital signal processing unit.

12. The apparatus as claimed in claim 8, further comprising a data register for depositing temporarily said signals generated by said digital signal processing unit.

13. The apparatus as claimed in claim 8, further comprising a image storage media usually constituted by a non-volatile memory unit for storing said image data compressed by said digital signal processing unit.

14. The apparatus as claimed in claim 13, wherein said image storage media can be selected from a mounted-in device and a removable memory device.

15. The apparatus as claimed in claim 8, wherein said mechanical shutter drive at least contains an electromagnetic valve.

16. The apparatus as claimed in claim 8, wherein said mechanical shutter drive at least contains a stepping motor.

17. The apparatus as claimed in claim 8, wherein said CMOS image sensor can be a passive-pixel sensor.

18. The apparatus as claimed in claim 8, wherein said CMOS image sensor can also be an active-pixel sensor for enhancing signal to noise ratio thereof.

19. The apparatus as claimed in claim 8, wherein said signal for eliminating residual image data is generated prior to said instruction for closing said mechanical shutter.

20. The apparatus as claimed in claim 8, wherein said instruction for closing said mechanical shutter is generated prior to said signal for eliminating residual image data adapted to said comparatively short exposure period.

21. The apparatus as claimed in claim 8, wherein said instruction for closing said mechanical shutter is generated after residual image data eliminated adapted to said comparatively long exposure period.

22. The apparatus as claimed in claim 8, wherein a delay exists between the point of time for closing said mechanical shutter completely and another point of time for starting to read out the image data acquired during said electronic exposure period of said CMOS image sensor.

23. The apparatus as claimed in claim 8, wherein said point of time for starting to read out the image data acquired during said electronic exposure period of said CMOS image sensor is after said instruction for closing said mechanical shutter finished.

24. The apparatus as claimed in claim 8, wherein said point of time for starting to read out the image data acquired during said electronic exposure period of said CMOS image sensor is prior to said instruction for closing said mechanical shutter finished.
